(19) United States
(12) Patent Application Publication
(10) Pub. No.: US 2026/0169035 A1
(43) Pub. Date: Jun. 18, 2026

(54) Circuit Arrangement for Measuring Current

(71) Applicant: Siemens Aktiengesellschaft, Muenchen (DE)

(72) Inventors: Jaroslaw KUSSYK, Wien (AT); Robert FRANKENBERG, Wien (AT)

(21) Appl. No.: 19/416,115

(22) Filed: Dec. 11, 2025

(30) Foreign Application Priority Data
Dec. 13, 2024 (DE) 102024211914.8

(51) Int. Cl. G01R 15/18; G01R 19/165; G01R 19/22

(52) U.S. Cl. CPC G01R 15/183; G01R 19/16547; G01R 19/22

(57) ABSTRACT

Circuit arrangement for measuring conductor current, wherein a current transformer generates an input voltage from the current, and a first output of a diode bridge circuit is located at the connection of two identical first electrodes of diodes, where a measuring resistor is inserted between two identical second electrodes of the diodes of the diode bridge circuit, a second output of the diode bridge circuit is located at the connection one diode to the second electrodes and the measuring resistor, and an extended bridge node is located at the connection of the other diodes, the second electrodes and measuring resistor, and diodes are formed by source-drain diodes of a first and second field-effect transistors, and a control apparatus actuates gates of the first and second field-effect transistors via a control voltage, and a measuring apparatus measures a measuring voltage at the measuring resistor that is proportional to the current.

### BACKGROUND OF THE INVENTION

### 1. Field of the Invention

The invention relates to a circuit arrangement for measuring current in a conductor through which a current flows, where a current transformer is configured to generate an input voltage from the current in the conductor, which is supplied to the input of a diode bridge circuit.

### 2. Description of the Related Art

In an electrical power distribution infrastructure, such as in intelligent DC and AC distribution networks (i.e., “smart grids”), information about a network state, such as voltage level, current load, power flow and/or power distribution, is usually determined by a plurality of distributed sensor units.

Here, sensor data is transmitted and evaluated centrally in a central unit for monitoring and possibly controlling the networks.

Here, it is important that the current/voltage measurement data captured in sensor units enables the calculation of active and reactive power.

In many applications of sensor units for current measurement in electrical AC distribution networks, it is advantageous for the sensor unit to draw power for its own supply from the current conductor in or upon which these are installed.

Inductive current transformers with a solid core made of magnetic material that enclose the current conductor are generally used for this purpose.

Here, the secondary winding of the current transformer is attached to a rectifier circuit, such as a diode bridge circuit, which provides the rectified current for the sensor unit's power supply.

For measuring current, a shunt resistor or measuring resistor is usually periodically connected in parallel to the secondary winding of the current transformer via an electronic switch at which a voltage proportional to the primary current of the current transformer is measured, as disclosed in EP4125180A1.

These electronic switches and the downstream circuitry face the challenge that the current measurement signal, i.e., the voltage across the shunt resistor, cannot be referenced directly to the ground of the power supply voltage, because it is effectively tapped upstream of the rectifier.

This requires a further differential amplifier, which entails higher system complexity or additional hardware costs.

In order to solve the last problem, circuit arrangements of sensor units are known that connect a measuring resistor in the form of a shunt resistor downstream of the rectifier circuit and thus dispense with the direct capture of an AC voltage measurement signal, where only the effective value of the primary current can be measured.

However, such a circuit arrangement is a major disadvantage if the sensor units are to be used for (distributed and) synchronous measurement of alternating currents with a reference alternating voltage for monitoring the load flow direction in electrical power distribution networks.

### SUMMARY OF THE INVENTION

In view of the foregoing, it is therefore and object of the invention to provide a solution for current measurement with reduced effort that does not require an additional external power supply.

This and other objects and advantages are achieved in accordance with the invention by a circuit arrangement for measuring current in a conductor through which a current flows, where a current transformer is configured to generate an input voltage from the current in the conductor, which is supplied to the input of a diode bridge circuit, and a first output of the diode bridge circuit is located at the connection of identical first electrodes of the diodes of the diode bridge circuit, where a measuring resistor for measuring current is inserted between the two identical second electrodes of the diodes of the diode bridge circuit, where the type of the second electrodes differs from the type of the first electrodes. In addition, a second output of the diode bridge circuit is located at the connection of one of the diodes to the second electrodes and the measuring resistor, and an extended bridge node is located at the connection of the other diodes to the second electrodes and the measuring resistor.

Further, the diode of the diode bridge circuit that is located at the second output is formed by the source-drain diode of a first normally-off field-effect transistor, and the diode of the diode bridge circuit, which is located at the extended bridge node is formed by the source-drain diode of a second normally-off field-effect transistor, where a control apparatus is configured to actuate the gate of the first field-effect transistor and the gate of the second field-effect transistor via a control voltage that is the same in each case, thereby switching the circuit arrangement between a charging mode for a capacitor connecting the first output to the extended bridge node and a measuring mode, and where a measuring apparatus is configured, in the switched measuring mode, to measure a measuring voltage at the measuring resistor which is proportional to the current in the conductor.

This achieves the application of the functions of both a rectifier and an analog switch in order to be able to use a shunt resistor without an additional differential amplifier for current measurement, as provided for in the prior art.

With the mode switching, the shunt resistor can be optionally connected for uninterrupted current measurement.

The circuit arrangement enables combined power harvesting from the line current and AC measurement while reducing implementation effort.

This makes it possible to implement a sensor unit for capturing AC current phasors or AC voltage phasors, which are to be transmitted from a plurality of sensor units to a central unit in a distributed measurement system.

This enables sufficiently accurate calculation of active and reactive power averages for load flow monitoring in electrical AC electrical distribution networks.

This also enables the use of power-saving wireless communication technologies, which is particularly advantageous in solutions with local power harvesting from the currents in individual phase conductors of a power supply network.

Here, the same control voltage for the voltages at the gates of the two field-effect transistors means that a voltage threshold value is reached or exceeded, i.e., the field-effect transistor is in an active or switched state or in a low-resistance saturation state.

In other words, applying the same gate voltage to both transistors field-effect transistors corresponds to switching the field-effect transistors from charging mode to measuring mode, i.e., logical switching of the two field-effect transistors.

The second output and the extended bridge node are clearly not located at the same connection point.

In other words, the second output and the extended bridge node are each located on different sides of the measuring resistor.

Hence, the diode bridge circuit is formed between the two inputs and the two outputs by a bridge circuit with diodes and diodes of field-effect transistors, where the diodes of the field-effect transistors can be switched by corresponding control voltages.

In one embodiment of the invention, the first input of the diode bridge circuit is connected to the extended bridge node via a further diode, and the type of electrode of the further diode corresponds to the type of electrodes of the diodes at the extended bridge node.

In another embodiment of the invention, the measuring apparatus is further configured to switch periodically between the charging mode and the measuring mode. This allows the capacitor to be primarily charged via the further diode of the diode bridge circuit. This achieves faster charging of the capacitor or reduces the necessary duration of the charging mode.

In addition, the measuring resistor can be protected from high transient pulse currents by the further diode. In charging mode, the capacitor is charged. In measuring mode, the voltage at the measuring resistor can be evaluated by the measuring apparatus. This allows the current flow in the conductor of the power supply network to be monitored periodically.

It is clear that the disclose embodiments of the invention can be applied separately to all conductors in a power supply network.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

The invention is described in more detail in the following figures with reference to an exemplary embodiment, in which:

FIG. 1 shows a schematic illustration of a current sensor in accordance with the prior art; and

FIGS. 2-5 show various exemplary embodiments of the invention.

### DETAILED DESCRIPTION OF THE EXEMPLARY EMBODIMENTS

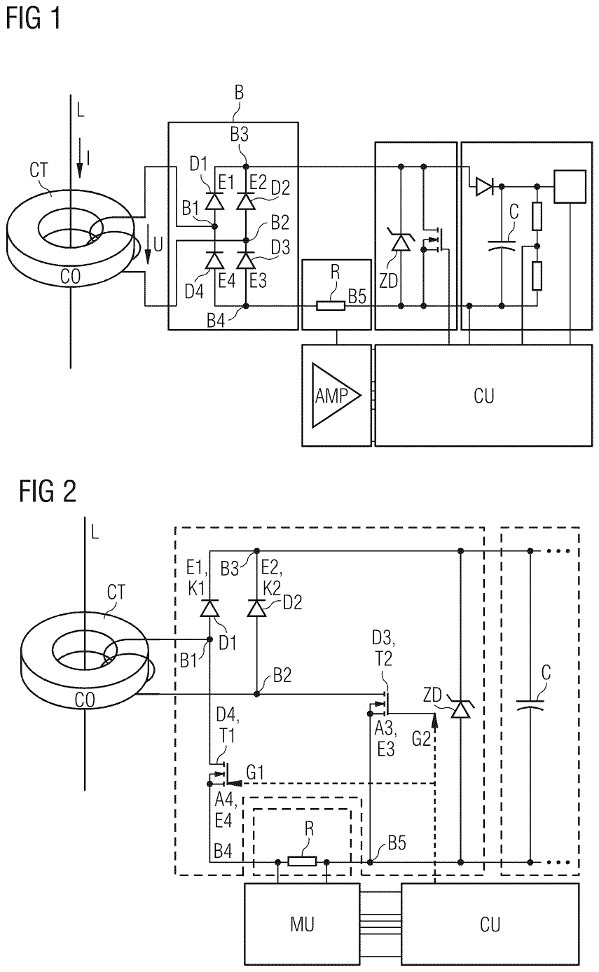

FIG. 1 shows a current sensor in accordance with the prior art, where a current-carrying network conductor L is enclosed by a core CO of the inductive current transformer CT in the disclosed circuit arrangement.

The secondary winding of the current transformer CT is attached to the AC voltage input of the rectifier in the form of a diode bridge circuit B with bridge nodes B1, B2, B3, B4 and a measuring resistor R at an extended bridge node B5.

The diode bridge circuit B comprises diodes D1, D2, D3 and D4, which also serve as references in the following figures.

A Zener diode ZD serves as a protective element for the circuit and a capacitor C serves for smoothing downstream of the rectifier B.

Accordingly, the circuit arrangement enables current measurement with the aid of the measuring resistor R, an amplifier AMP and a control circuit CU in a conductor L through which a current I flows.

A current transformer CT is configured to generate an input voltage U from the current I in the conductor L, which is supplied to the input B1, B2 of a diode bridge circuit B, and a first output B3 of the diode bridge circuit B is located at the connection of identical first electrodes E1, E2 of diodes D1, D2 of the diode bridge circuit B.

The first electrodes E1, E2 of diodes D1, D2 are their cathodes K1, K2.

FIG. 2 depicts a first exemplary embodiment of the circuit arrangement in accordance with the invention with a diode bridge circuit, which is based on the above-described prior art arrangement.

The first electrodes E1, E2 in the form of respective cathodes K1, K2 of diodes D1, D2 are located at the first output B3 of the diode bridge circuit B.

In the circuit arrangement, a current-carrying network conductor L is enclosed by a core CO of the inductive current transformer CT.

The secondary winding of the current transformer CT is attached to the AC voltage input with the inputs B1 and B2 of the rectifier in the form of a diode bridge circuit B.

The diode bridge circuit B comprises diodes D1, D2 and a first n-channel field-effect transistor T1 and a second n-channel field-effect transistor T1 which, in their off state, each perform the function of a diode.

The diode bridge circuit B also contains a measuring resistor R between the two electrodes E3, E4, which is sufficiently sized (i.e., small) so as not to significantly affect the rectifier functionality of the bridge circuit B or the charging of the capacitor C.

The gate terminals of the first and second n-channel field-effect transistors T1, T2 form circuit nodes G1, G2, which can, for example, be actuated together.

The first and second field-effect transistors T1, T2 each comprise an n-channel FE which, in the off state, behaves as a diode.

The sensor unit with a measuring resistor R can be supplied with power via the rectifier B and the capacitor C can be charged.

Once the capacitor C has stored enough charge, the circuit is switched from charging state to measuring state.

To do this, the same voltage is applied to both gate terminals G1, G2 of FETs T1 and T2 relative to ground, the extended bridge node B5. As a result, the two FETs T1, T2 are low-impedance between their source terminals and drain terminals and connect the shunt resistor or measuring resistor R to the two terminals of the secondary winding of the current transformer CT, i.e., the inputs B1, B2.

Diodes D1 and D2 remain in the off state and therefore do not discharge the capacitor C1 because, in this state, they are biased relative to ground B5 by the voltage at the charged capacitor C1 and are also connected between the circuit nodes B1 and B2 in opposite directions to each other.

The second electrodes E3, E4 of diodes D3, D4 formed by the transistors T1, T2 are their anodes A3, A4 and are located at the second output B4.

A diode D4 of the diode bridge circuit B, which is located at the second output B4, is formed by the source-drain diode of a first normally-off field-effect transistor T1.

A control apparatus CU is configured to actuate the gate of the first field-effect transistor T1 and the gate of the second field-effect transistor T2 via an identical control voltage at the nodes G1 and G2, thereby switching the circuit arrangement between a charging mode for the capacitor C connecting the first output B3 to the measuring resistor R at the extended bridge node B5 and a measuring mode.

This results in a series connection of measuring resistor R and capacitor C between the first output B3 and the second output B4.

A Zener diode ZD can be arranged parallel to the capacitor C to protect the circuit.

The nodes G1, G2 are only “logical” representations because the control voltages can, for example, be provided by respective voltage dividers, hence the dashed lines.

When switched to measuring mode, a measuring apparatus MU is configured to measure a measuring voltage at the measuring resistor R between the node B4 and the extended bridge node B5 which is proportional to the current I in the conductor L.

The measuring apparatus MU is furthermore configured to switch periodically between charging mode and measuring mode.

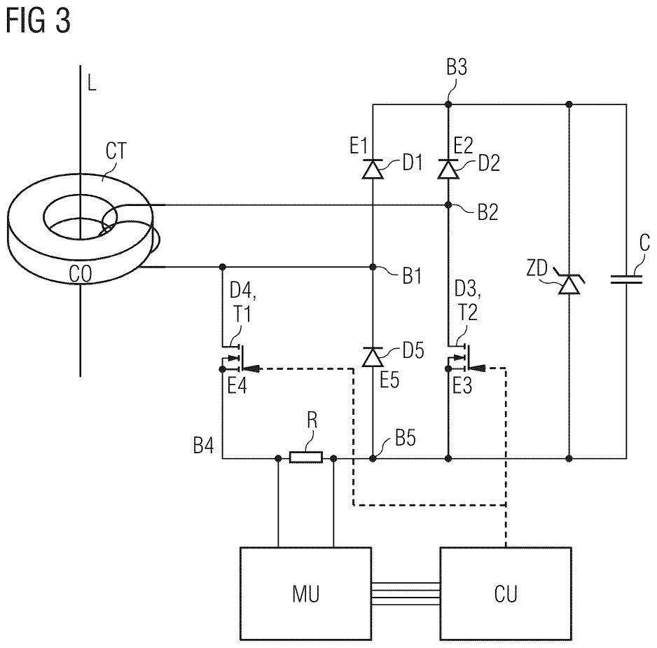

FIG. 3 depicts a second exemplary embodiment of the circuit arrangement in accordance with the invention.

The explanations relating to the preceding figure also apply here.

In addition to the preceding figure, a further diode D5 is inserted between the first input B1 and the extended bridge node B5 of the diode bridge circuit B, where the type of electrode of diode D4, which is formed by the transistor T1, and the further diode D5 at the connection point are the same.

In this exemplary embodiment, the electrode E5 of the further diode D5 at the extended bridge node B5 is an anode.

The sum of the measuring resistor R and the source-drain resistor of the first normally-off field-effect transistor T1 is dimensioned such that the measuring voltage remains below the threshold voltage of the further diode D5 of the diode bridge circuit B, which is connected to the source terminal of the second normally-off field-effect transistor T2.

The measuring resistor R can be dimensioned accordingly.

The capacitor C is primarily charged via diodes D1, D2, D3 and the further diode D5 of the diode bridge circuit B. However, the charging also occurs in part via diode D4 and the measuring resistor R that are connected in parallel to the further diode D5. This achieves faster charging of the capacitor C or reduces the necessary duration of the charging mode.

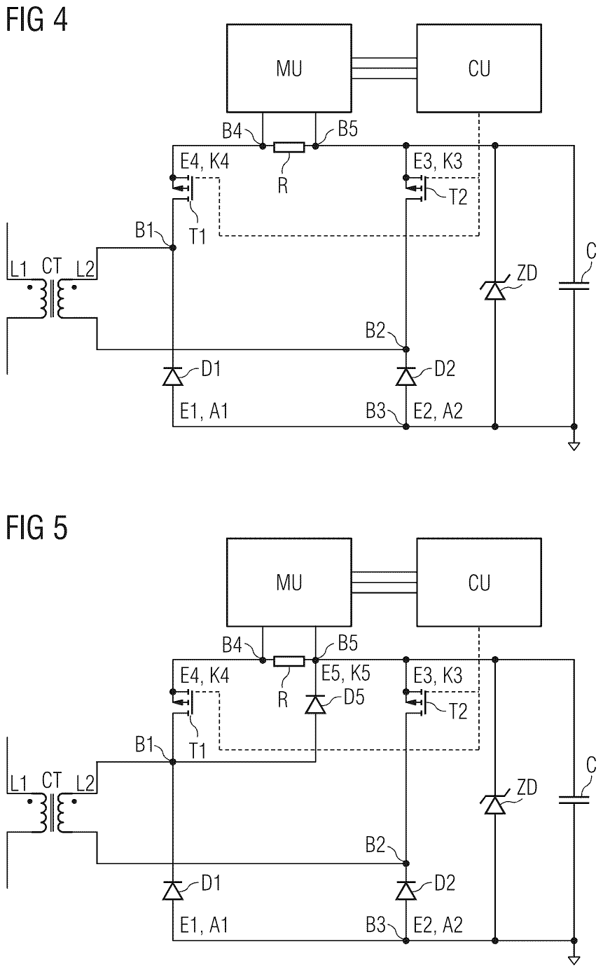

FIG. 4 depicts a third exemplary embodiment of the circuit arrangement in accordance with the invention. Here, the first and the second normally-off field-effect transistors T1, T2 each comprises a p-channel transistor.

This embodiment is functionally equivalent to the circuit in FIG. 2 with the n-channel transistors T1, T2, but the polarity of the current transformer CT and the actuation of the transistors T1, T2 can, for example, be taken into account accordingly.

Diodes D1, D2 are connected via their anodes A1, A2, which correspond to the electrodes E1, E2, here.

Diodes D3, D4, formed by the transistors T1, T2, are connected via their cathodes K1, K2, which correspond to the electrodes E3, E4 here.

The current transformer CT can comprise windings L1, L2, where the winding L1 can be formed by the conductor L, which is enclosed by the core CO according to the preceding figures.

It is also possible in the exemplary embodiments in FIGS. 2 and 3 for the current transformer to have a plurality of windings on both sides.

FIG. 5 depicts a fourth exemplary embodiment of the circuit arrangement in accordance with the invention. Here, the first and the second normally-off field-effect transistors T1, T2 each comprise a p-channel transistor.

This embodiment is functionally equivalent to the circuit in FIG. 3 with the n-channel transistors T1, T2, but the polarity of the current transformer CT and the actuation of the transistors T1, T2 can, for example, be taken into account accordingly.

Diodes D1, D2 are connected via their anodes A1, A2, which correspond to the electrodes E1, E2 here.

Diodes D3, D4, formed by the transistors T1, T2, are connected via their cathodes K1, K2, which correspond to the electrodes E3, E4 here.

Furthermore, the first input B1 of the diode bridge circuit B is connected to the extended bridge node B5 via a further diode D5.

The cathode K5 of the further diode D5 is connected to the cathode K3 of the diode formed by the second transistor T2.

Thus, while there have been shown, described and pointed out fundamental novel features of the invention as applied to a preferred embodiment thereof, it will be understood that various omissions and substitutions and changes in the form and details of the devices illustrated, and in their operation, may be made by those skilled in the art without departing from the spirit of the invention. For example, it is expressly intended that all combinations of those elements that perform substantially the same function in substantially the same way to achieve the same results are within the scope of the invention. Moreover, it should be recognized that structures and/or elements shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

What is claimed is:

1. A circuit arrangement for measuring current in a conductor through which a current flows, the arrangement comprising:
a current transformer configured to generate an input voltage from the current in the conductor;
a diode bridge circuit, the current being supplied to an input of the diode bridge circuit, and a first output of the diode bridge circuit being located at a connection of two identical first electrodes of diodes of the diode bridge circuit;
a measuring resistor for measuring current inserted between two identical second electrodes of the diodes of the diode bridge circuit, a the type of the second electrodes differs from a type of the first electrodes;
a second output of the diode bridge circuit located at a connection of one diode of the diodes diode bridge circuit to the second electrodes and the measuring resistor;
an extended bridge node is located at the connection of the other diodes to the second electrodes and the measuring resistor, a diode of the diode bridge circuit which is located at the second output being formed by a source-drain diode of a first normally-off field-effect transistor, and a diode of the diode bridge circuit, which is located at the extended bridge node being formed by a source-drain diode of a second normally-off field-effect transistor;
a control apparatus configured to actuate a gate of the first field-effect transistor and a gate of the second field-effect transistor via a control voltage which is identical in each case to switch the circuit arrangement between a charging mode for a capacitor connecting the first output to the extended bridge node and a measuring mode; and
a measuring apparatus configured, in the switched measuring mode, to measure a measuring voltage at the measuring resistor which is proportional to the current in the conductor.

2. The circuit arrangement as claimed in claim 1, wherein the first input of the diode bridge circuit is connected to the extended bridge node via a further diode, and a type of electrode of the further diode corresponds to the type of electrodes of the diodes at the extended bridge node.

3. The circuit arrangement as claimed in claim 1, wherein the measuring apparatus is further configured to periodically switch between the charging mode and the measuring mode.
